(19) United States
(12) Patent Application Publication
(10) Pub. No.: US 2013/0102105 A1
(43) Pub. Date: Apr. 25, 2013

(54) PRODUCTION METHOD OF SOLAR CELL MODULE

(71) Applicants: Kazuyuki Nakata, Ichihara-shi (JP); Kazuyuki Oogi, Ichihara-shi (JP); Yui Endo, Ichihara-shi (JP)

(72) Inventors: Kazuyuki Nakata, Ichihara-shi (JP); Kazuyuki Oogi, Ichihara-shi (JP); Yui Endo, Ichihara-shi (JP)

(73) Assignee: DU PONT-MITSUI POLYCHEMICALS CO., LTD., Tokyo (JP)

(21) Appl. No.: 13/808,412

(22) PCT Filed: Jul. 8, 2011
(86) PCT No.: PCT/JP2011/065729

§ 371 Date: Jan. 4, 2013

(30) Foreign Application Priority Data
Jul. 9, 2010 (JP) 2010-157205

(51) Int. Cl. H01L 31/20

(52) U.S. Cl. CPC H01L 31/202
USPC 438/64

(57) ABSTRACT

The present invention provides a production method of a solar cell module, comprising: a first process of mounting a module layered body, which comprises at least a glass member, an encapsulant, a solar cell element and a translucent member in this order, and in which an outer periphery of the encapsulant is positioned at an inner side of outer peripheries of the glass member and the translucent member, on a mounting platen of a double vacuum chamber system laminator comprising a first chamber and a second chamber that are partitioned by a flexible member, and the mounting platen, which is provided in the second chamber facing the flexible member and comprises a heating means, the module layered body being mounted on the mounting platen so that the glass member is at the flexible member side; a second process of depressurizing the inside of the first chamber and the inside of the second chamber; and a third process of heat-pressure bonding and integrating the module layered body by raising a pressure in the first chamber to from 0.005 MPa to 0.090 MPa (gauge pressure of from −0.096 MPa to −0.011 MPa) and pressing the module layered body to the heated mounting platen by the flexible member which has undergone flexural deformation.

### TECHNICAL FIELD

The present invention relates to a production method of a solar cell module.

### BACKGROUND ART

A solar cell element is often produced using a monocrystalline silicon substrate or a polycrystalline silicon substrate. Further, the configuration of a solar cell module including a solar cell element is usually a configuration in which an encapsulant having an ethylene-vinyl acetate copolymer (EVA) or the like as a main component is enclosed between a translucent substrate and a back face protective member, and the solar cell element is encapsulated by the encapsulant. The reason for providing the solar cell module with the aforementioned configuration is because the solar cell element is vulnerable to physical impact, and furthermore, because it is necessary to protect the solar cell element from weathering or physical damage when the solar cell module is installed outdoors.

As a method of producing the solar cell module, a production method wherein a module layered body obtained by superposing the translucent substrate, the encapsulant, the solar cell element, the encapsulant, and the back face protective member in this order is prepared, and the module layered body is heat-pressure bonded and integrated using a double vacuum chamber system laminator to obtain the solar cell module, is common.

FIG. 7 is a schematic cross-sectional view showing one example of a double vacuum chamber system laminator.

The double vacuum chamber system laminator shown in FIG. 7 comprises a diaphragm (hereinafter, sometimes referred to as a “flexible member”) 101 (for example, a diaphragm made of silicon rubber), an upper chamber (hereinafter, sometimes referred to as a “first chamber”) 102 and a lower chamber (hereinafter, sometimes referred to as a “second chamber”) 104 that are partitioned by the diaphragm 101, and a mounting platen 103 that is provided in the lower chamber 104. A heater 133 is built into the mounting platen 103. A module layered body 207 serving as an object of heat-pressure bonding treatment is mounted at the mounting platen 103.

FIG. 8 is a schematic cross-sectional view showing the module layered body 207 which is one example of a conventional module layered body. As shown in FIG. 8, the module layered body 207 has a configuration in which a translucent substrate 221, an encapsulant 222, a solar cell element 223, an encapsulant 224 and a back face protective member 225 are superposed in this order. The translucent substrate 221, the encapsulant 222, the encapsulant 224 and the back face protective member 225 are arranged so that outer peripheries of these respective members overlap when viewed from a normal direction of these respective members (in this regard, shapes and sizes, viewed from the normal direction, of the respective members are the same).

One example of a production method using the laminator shown in FIG. 7 will be explained below as one example of a conventional production method of a solar cell module.

(1) The translucent substrate 221, the encapsulant 222, the solar cell element 223, the encapsulant 224 and the back face protective member 225 are superposed in this order to form the module layered body 207. Next, the lower chamber 104 is opened, and the module layered body 207 is mounted on the mounting platen 103 such that the translucent substrate 221 is at the mounting platen 103 side and the back face protective member 225 is at the diaphragm 101 side. Thereafter, the lower chamber 104 is closed.

(2) The upper chamber 102 is subjected to vacuum depressurization.

(3) Simultaneously with stopping vacuum depressurization of the upper chamber 102, vacuum depressurization is also carried out with respect to the lower chamber 104.

(4) Heating of the encapsulants 224 and 222 is carried out by heating the mounting platen 103 by the heater 133. Heating of the encapsulants 224 and 222 is carried out until a temperature at which a resin constituting the encapsulants 224 and 222 softens or melts is reached.

(5) Next, the upper chamber 102 is returned to atmospheric pressure while maintaining the vacuum depressurization of the lower chamber 104, the module layered body 207 is pressed toward the mounting platen 103 by the diaphragm 101 by utilizing the pressure difference between the lower chamber 104 and the upper chamber 102, and the module layered body 207 is heat-pressure bonded.

(6) In a case where the resin constituting the encapsulants 224 and 222 is a resin that requires a cross-linking reaction (for example, an ethylene-vinyl acetate copolymer (EVA)), the encapsulants 224 and 222 are further heated to a temperature at which a cross-linking reaction is caused, and that temperature is maintained until the cross-linking is completed.

(7) After a sufficient pressure bonding time elapses, the lower chamber 104 is returned to atmospheric pressure. Thereafter, the lower chamber 104 is opened up, and the solar cell module obtained by integrating the module layered body 207 is taken out.

In a conventional production method of a solar cell module such as that described above, there are cases where air bubbles are generated in the produced solar cell module. Generation of air bubbles causes delamination from a location thereof, intrusion of rainwater and insulation defects and is therefore not preferable. The air bubbles come from a variety of causes such as insufficient evacuation (deairing) of air that is present between the respective bonded members, insufficient evacuation (deairing) of air that is caught in the melting encapsulants, insufficient evacuation (deairing) of volatile components that are contained in materials constituting the respective members, and the like.

Various methods have been proposed in order to prevent air bubbles in a solar cell module.

For example, a method for preventing a foaming phenomenon caused by rapid decomposition of a cross-linking agent contained in the encapsulants is known (for example, refer to Japanese Patent No. 4401649).

Further, a method of initiating heating after conducting preliminary pressure application to carry out the heat-pressure bonding is known (for example, refer to Japanese Patent Application Laid-Open (JP-A) No. 2003-282920).

Also, a method of carrying out the heat-pressure bonding after leaving the layered body in a vacuum state for a short time before heating is known (for example, refer to Japanese Patent No. 2915327).

Furthermore, a double vacuum chamber system laminator that uses induction heating is known (for example, refer to JP-A No. 2010-23485).

Further, an encapsulating method for a solar cell module, wherein, by preheating the diaphragm to a predetermined temperature before pressing and heating a body to be laminated, generation of large temperature difference between a side of the face that contacts the mounting platen and a side of the face that is pressed by the diaphragm can be prevented at the time of pressing and heating of the body to be laminated, is known (for example, refer to Japanese Patent No. 4347454).

Furthermore, as a production method of a solar cell module having good appearance in which residual air bubbles, movement of the solar cell or squeezing out of an encapsulating resin from an end face can be suppressed, a production method of a solar cell module, wherein a pressure inside an encapsulation processing container is adjusted to 0.05 MPa or higher and to equal to or less than atmospheric pressure, is known (for example, refer to Japanese Patent No. 3875715 and International Publication (WO) No. 2004/038811).

### DISCLOSURE OF INVENTION

### Problems to be Solved by the Invention

However, according to study by the present inventors, it has been found that, in a method using a double vacuum chamber system laminator in which the module layered body is pressed by the diaphragm by returning the evacuated upper chamber to atmospheric pressure to obtain the solar cell module, in a case where a glass member is included as a member of the module layered body, air bubbles are easily generated in a corner portion of the solar cell module.

Further, conventionally, a module layered body configured such that outer peripheries of the respective members overlap, as in the module layered body 207 shown in FIG. 7, has often been used as the module layered body. In a module layered body having such a configuration, melted encapsulant is squeezed out from the outer peripheries of the translucent substrate and the back face protective member after heat-pressure bonding treatment. In this regard, removal of encapsulant that has been squeezed out from the outer peripheries of the translucent substrate and the back face protective member has conventionally been carried out after the heat-pressure bonding treatment. This operation for removal of the encapsulant is called trimming.

In recent years, in order to omit the aforementioned trimming, encapsulants that are smaller than the translucent substrate and the back face protective member have been used, and the structure of the module layered body has been made to be a structure in which outer peripheries of the encapsulants are arranged at an inner side of the outer peripheries of the translucent substrate and the back face protective member. As a result, squeezing out of encapsulant due to the heat-pressure bonding treatment is prevented.

However, according to studies by the present inventors, it has become clear that, in a case where the structure of the module layered body is made to be the aforementioned “structure in which outer peripheries of the encapsulants are arranged at an inner side of the outer peripheries of the translucent substrate and the back face protective member” and the module layered body is heat-pressure bonded using a conventional production method of a solar cell module, it is easy for the shapes of the encapsulants to be deformed by the heat-pressure bonding treatment.

The present invention has been achieved in view of the aforementioned circumstances. Under the aforementioned circumstances, a production method of a solar cell module by which generation of air bubbles at corner portions is suppressed and deformation of the encapsulants by the heat-pressure bonding treatment is suppressed, at the time of producing the solar cell module, is demanded.

### Means for Solving the Problem

Concrete means for solving the aforementioned problems are as follows.

<1> A production method of a solar cell module, comprising: a first process of mounting a module layered body, which comprises at least a glass member, an encapsulant, a solar cell element and a translucent member in this order, and in which an outer periphery of the encapsulant is positioned at an inner side of outer peripheries of the glass member and the translucent member, on a mounting platen of a double vacuum chamber system laminator comprising a flexible member, a first chamber and a second chamber that are partitioned by the flexible member, and the mounting platen, which is provided in the second chamber facing the flexible member and comprises a heating means, the module layered body being mounted on the mounting platen so that the glass member is at the flexible member side; a second process of depressurizing the inside of the first chamber and the inside of the second chamber after the first process; and a third process of heat-pressure bonding and integrating the module layered body by raising a pressure in the first chamber to from 0.005 MPa to 0.090 MPa (gauge pressure of from −0.096 MPa to −0.011 MPa) and pressing the module layered body to the heated mounting platen by the flexible member which has undergone flexural deformation, after the second process.
<2> The production method of a solar cell module according to <1>, wherein a bending elastic modulus of the translucent member is 1 GPa or greater.
<3> The production method of a solar cell module according to <1> or <2>, wherein the translucent member is a glass member.
<4> The production method of a solar cell module according to any one of <1> to <3>, wherein the encapsulant comprises an ionomer of an ethylene-unsaturated carboxylic acid copolymer.
<5> The production method of a solar cell module according to any one of <1> to <4>, wherein the module layered body comprises the encapsulant and the glass member, in this order, on an amorphous silicon solar cell element of the translucent member, on which the amorphous silicon solar cell element is formed.
<6> The production method of a solar cell module according to any one of <1> to <5>, wherein the module layered body comprises the encapsulant, which contains an ionomer of an ethylene-unsaturated carboxylic acid copolymer, and the glass member, in this order, on an amorphous silicon solar cell element of the translucent member, on which the amorphous silicon solar cell element is formed.
<7> The production method of a solar cell module according to any one of <1> to <6>, wherein a thickness of the glass member is 4 mm or less.
<8> The production method of a solar cell module according to any one of <1> to <7>, wherein a distance between the outer periphery of the encapsulant and the outer peripheries of the glass member and the translucent member is from 1.5 mm to 25 mm.

### Effects of the Invention

According to the present invention, a production method of a solar cell module, by which generation of air bubbles at corner portions is suppressed and deformation of the encapsulant by the heat-pressure bonding treatment is suppressed, at the time of producing the solar cell module, can be provided.

### BRIEF DESCRIPTION OF DRAWINGS

FIG. 1 is a schematic cross-sectional view showing one example of a laminator which is preferably used in the present invention.

FIG. 2 is a schematic cross-sectional view showing one example of a module layered body in the present invention.

FIG. 3 is a schematic cross-sectional view showing another example of the module layered body in the present invention.

FIG. 4 is a photograph showing a corner portion of a solar cell module according to Comparative Example 1.

FIG. 5 is a photograph showing the entirety of a solar cell module according to Example 2.

FIG. 6 is a photograph showing the entirety of a solar cell module according to Comparative Example 3.

FIG. 7 is a schematic cross-sectional view showing one example of a conventional laminator.

FIG. 8 is a schematic cross-sectional view showing one example of a conventional module layered body.

### BEST MODE FOR CARRYING OUT THE INVENTION

A production method of a solar cell module of the present invention comprises: a first process of mounting a module layered body, which comprises at least a glass member, an encapsulant, a solar cell element and a translucent member in this order, and in which an outer periphery of the encapsulant is positioned at an inner side of outer peripheries of the glass member and the translucent member, on a mounting platen of a double vacuum chamber system laminator comprising a flexible member, a first chamber and a second chamber that are partitioned by the flexible member, and the mounting platen, which is provided in the second chamber and comprises a heating means, the module layered body being mounted on the mounting platen so that the glass member is at the flexible member side; a second process of depressurizing the inside of the first chamber and the inside of the second chamber; and a third process of heat-pressure bonding and integrating the module layered body to obtain a solar cell module, by raising a pressure in the first chamber to from 0.005 MPa to 0.090 MPa (gauge pressure of from −0.096 MPa to −0.011 MPa) and pressing the module layered body to the heated mounting platen by the flexible member which has undergone flexural deformation, after the second process.

According to the production method of a solar cell module of the present invention, generation of air bubbles at corner portions is suppressed, and deformation of the encapsulant by the heat-pressure bonding treatment is suppressed, at the time of producing the solar cell module.

The reasons why the aforementioned effects are obtained are presumed to be as follows. However, the present invention is not limited by the following reasons.

In the conventional production method of a solar cell module, at the time of pressing the module layered body comprising the back face protective member, the encapsulant, the solar cell element, the encapsulant, and the translucent substrate in this order with the diaphragm to carry out heat-pressure bonding treatment using the double vacuum chamber system laminator, the upper chamber was raised to atmospheric pressure (0.101 MPa; that is, a gauge pressure of 0 MPa).

However, in the aforementioned conventional production method, in a case where a glass member (glass sheet) was used as the back face protective member, the following problems occurred due to the fact that the glass member has a high rigidity (bending elastic modulus) and the fact that the pressure bonding force (pressing) is too strong.

That is to say, after the heat-pressure bonding treatment, at the time when the lower chamber is returned to atmospheric pressure and the glass member is released from the pressure by the diaphragm, a repelling force that repels from a state of being pressed by the diaphragm and bent and attempts to return to an original shape acts strongly with respect to the glass member. That is to say, due to the pressing by the diaphragm and the release from the pressing, a large change in stress occurs in the glass member. Due to the change in stress at this time, air bubbles become more easily generated, particularly at corner portions of the glass member where the change in stress is concentrated.

This phenomenon is a peculiar phenomenon, which occurs in cases where the glass member is included as a member of the module layered body (solar cell module), and which does not occur in cases where a glass member is not included in the module layered body (solar cell module) (for example, in a case where a plastic film is used in place of the glass member).

In contrast with the aforementioned conventional production method, in the production method of a solar cell module of the present invention, the pressure in the first chamber is raised to 0.090 MPa or less, which is lower than atmospheric pressure, in the third process. For this reason, compared with the conventional method in which the pressure in the first chamber is raised to atmospheric pressure in the third process, the pressure difference between the inside of the first chamber and the inside of the second chamber is moderated, and by extension, the pressure bonding force applied to the module layered body is reduced, and the pressure bonding force applied to the glass member is also reduced. As a result, at the time of releasing the second chamber to atmospheric pressure to take out the module layered body after the third process, the repelling force that occurs in the glass member and the change in stress that occurs due to the pressing by the diaphragm and the release from the pressing can be made smaller compared with the conventional production method.

Accordingly, according to the production method of a solar cell module of the present invention, generation of air bubbles at corner portions of the glass member where the change in stress is concentrated can be suppressed.

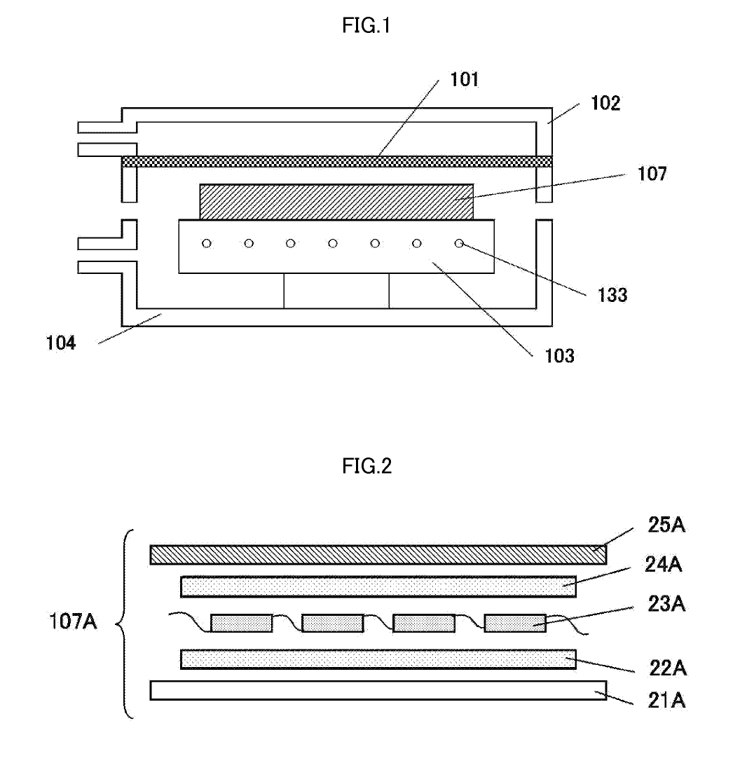

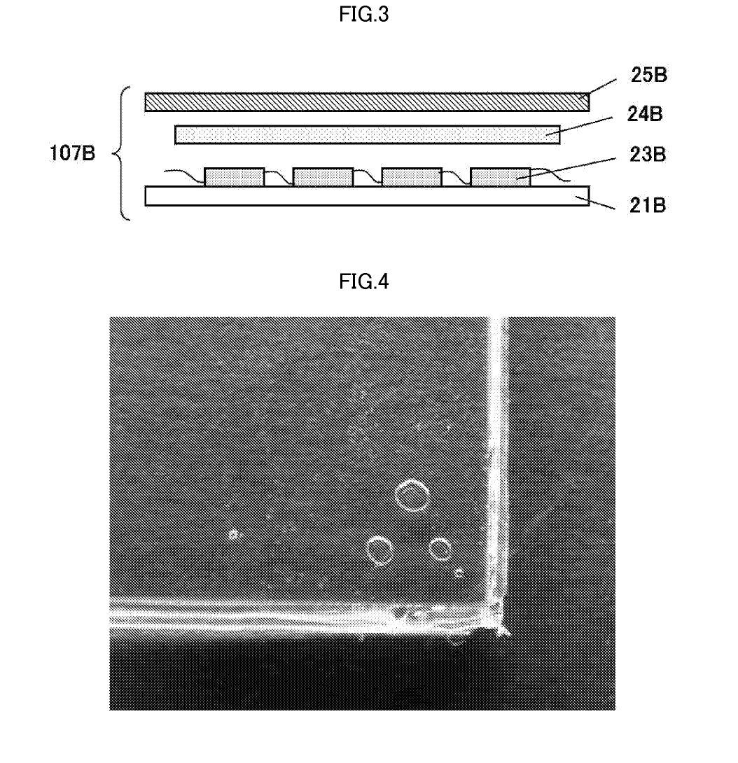

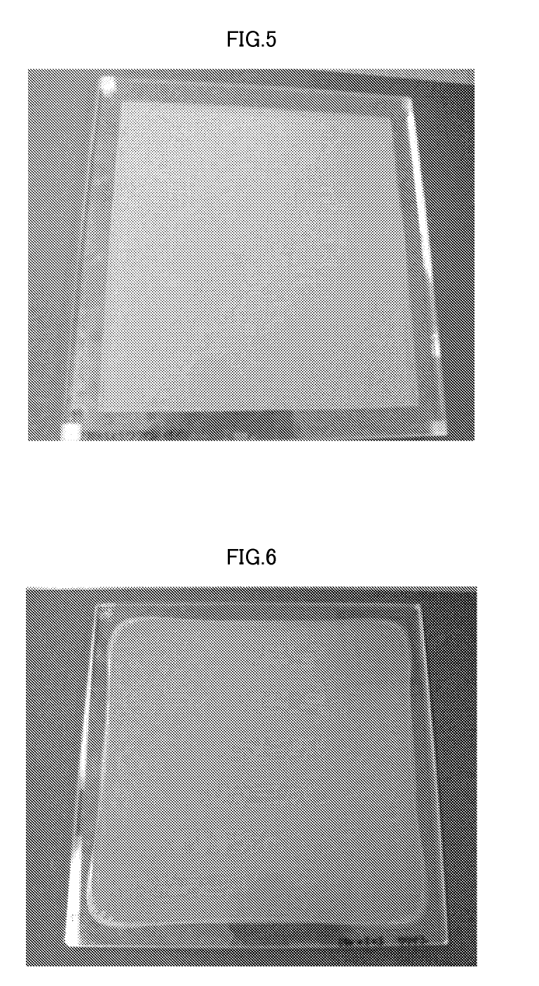

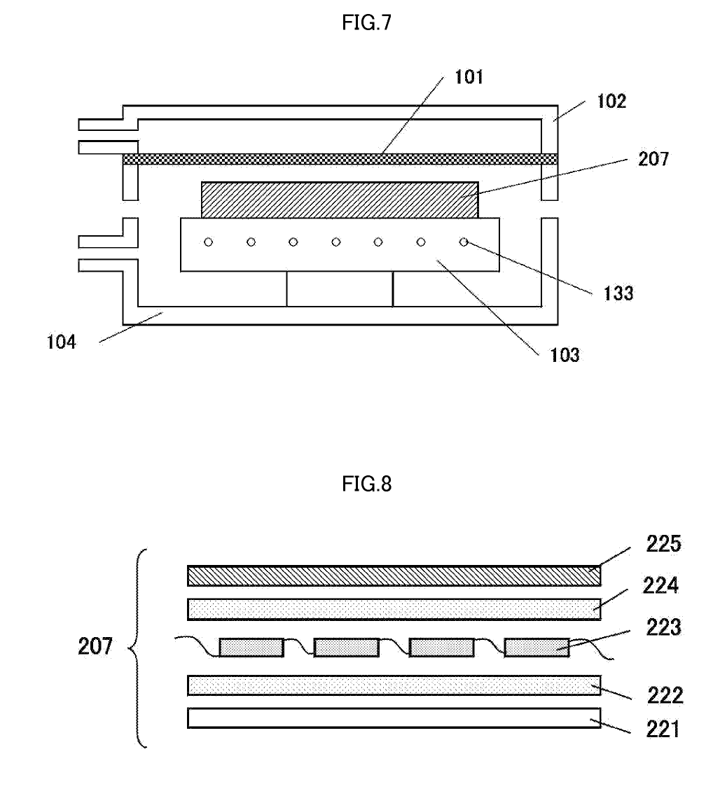

Moreover, in the aforementioned conventional production method, in a case where the module layered body which comprises at least the glass member, the encapsulant, the solar cell element and the translucent member in this order, and in which the outer periphery of the encapsulant is positioned at the inner side of the peripheries of the glass member and the translucent member (for example, refer to FIG. 2, FIG. 3 and FIG. 5 which will be described later) is integrated to obtain the solar cell module, the encapsulant is deformed by the heat-pressure bonding treatment due to the fact that the glass member has a high rigidity (bending elastic modulus) and the fact that the pressing (pressure bonding force) is too strong, and there are times when problems occur with respect to appearance. For example, due to the heat-pressure bonding treatment, there are times when the shape of the encapsulant deforms to a shape in which the corner portions are rounded or deforms to a shape in which centers of the respective sides deform inward toward the inner side (for example, refer to FIG. 6 which will be described later).

This phenomenon is also a peculiar phenomenon, which occurs in cases where the glass member is included as a member of the module layered body (solar cell module), and which does not occur in cases where a glass member is not included in the module layered body (solar cell module) (for example, in a case where a plastic film is used in place of the glass member). The reason for this is presumed to be because the pressure bonding force applied at the time of the heat-pressure bonding treatment can be allowed to escape uniformly since the plastic film has a low rigidity (bending elastic modulus) compared with the glass member and is flexible.

In contrast with the aforementioned conventional production method, in the production method of a solar cell module of the present invention, the pressure in the first chamber is raised to 0.090 MPa or less, which is lower than atmospheric pressure, in the third process, and therefore, the pressure bonding force applied to the encapsulant can be reduced, and deformation of the encapsulant by the heat-pressure bonding treatment can be suppressed.

Furthermore, in the production method of a solar cell module of the present invention, the pressure in the first chamber is raised to 0.005 MPa or greater in the third process, and therefore, pressure bonding force with respect to the module layered body can be sufficiently secured.

This pressure bonding force obtained in the third process is a sufficient pressure bonding force to evacuate gas within the module layered body, and therefore, generation of air bubbles due to deairing deficiency within the module layered body can be suppressed. As a result, according to the production method of a solar cell module of the present invention, generation of air bubbles throughout the entire face of the solar cell module, including the corner portions, can be prevented.

It is considered that, due to the foregoing reasons, according to the production method of a solar cell module of the present invention, the solar cell module can be produced while suppressing generation of air bubbles at the corner portions and suppressing deformation of the encapsulant by the heat-pressure bonding treatment.

Embodiments of the production method of a solar cell module of the present invention will be explained below while referencing the drawings.

FIG. 1 is a schematic cross-sectional view showing an embodiment of a double vacuum chamber system laminator which is preferably used in the production method of a solar cell module of the present invention.

As shown in FIG. 1, the double vacuum chamber system laminator in the present embodiment comprises a diaphragm 101 as a flexible member, an upper chamber 102 as a first chamber, and a lower chamber 104 as a second chamber.

The upper chamber 102 and the lower chamber 104 are partitioned by the diaphragm 101. That is to say, an interior space of the upper chamber 102 is formed by inner walls of the upper chamber 102 and the diaphragm 101, and an interior space of the lower chamber 104 is formed by inner walls of the lower chamber 104 and the diaphragm 101.

The lower chamber 104 is configured so as to be able to be opened and closed (FIG. 1 shows a state in which the lower chamber 104 is opened).

In the present embodiment, the module layered body 107 is put in and taken out (for example, to carry out the operation of the first process) when the lower chamber 104 is in the opened state, and pressure inside the upper chamber 102 is changed (for example, to carry out the operation of the third process) when the lower chamber 104 is in the closed state.

As shown in FIG. 1, the upper chamber 102 and the lower chamber 104 respectively have vent holes and are configured so that the pressure inside the chamber can be raised or lowered by suction or evacuation via the vent holes. For example, in the case of lowering the pressure inside the chamber, the inside of the chamber is evacuated through the vent holes by an unillustrated evacuation means (for example, a vacuum pump). For example, in the case of raising the pressure inside the chamber, air, nitrogen or the like is supplied to the inside of the chamber through the vent holes by an unillustrated gas supply means.

Incidentally, the upper chamber 102 and the lower chamber 104 are not limited by the embodiment shown in FIG. 1 and may be configured to separately comprise suction holes and evacuation holes.

The diaphragm 101 is a flexible member that undergoes flexural deformation in accordance with the pressure difference between the upper chamber 102 and the lower chamber 104, and, for example, is configured by silicon rubber or the like.

The module layered body 107 is pressed toward a mounting platen 103 by the diaphragm 101 which has undergone flexural deformation.

The mounting platen 103 is provided in the lower chamber 104. A surface of the mounting platen 103 faces the diaphragm 101.

The module layered body 107 is mounted on the mounting platen 103.

Furthermore, a heater 133 (heating means) for heating the module layered body 107 is built into the mounting platen 103.

The laminator according to the present embodiment is configured so that, when the module layered body 107 is mounted on the mounting platen 103 and the lower chamber 104 is closed, a gap (clearance) is provided between the module layered body 107 and the diaphragm 101.

This gap, that is, a distance between the module layered body 107 and the diaphragm 101, is ordinarily from 5 mm to 200 mm, and preferably from 10 mm to 100 mm.

The module layered body (for example, the module layered body 107) in the present invention comprises at least a glass member, an encapsulant, a solar cell element and a translucent member in this order and is provided with a configuration in which an outer periphery of the encapsulant is positioned at an inner side of outer peripheries of the glass member and the translucent member (for example, refer to FIG. 2, FIG. 3 and FIG. 5 which will be described later). That is to say, a size of the encapsulant is smaller than a size of the glass member and the translucent member.

The size and shape of the glass member and the translucent member are not particularly limited, but quadrangular (square or rectangular) members with each side being from 200 mm to 3000 mm can be used as the glass member and the translucent member.

The size and shape of the encapsulant is not particularly limited, but a quadrangular (square or rectangular) member with each side being from 3 mm to 50 mm (more preferably from 4 mm to 25 mm) shorter than each side of the glass member and the translucent member can be used as the encapsulant.

In this regard, “size” and “shape” refer to a size and a shape when viewed from a normal direction (the same applies hereinafter).

A distance between the outer periphery of the encapsulant and the outer peripheries of the glass member and the translucent member is preferably from 1.5 mm to 25 mm, and more preferably from 2 mm to 12.5 mm.

If the distance between the outer periphery of the encapsulant and the outer peripheries of the glass member and the translucent member is 1.5 mm or more, a phenomenon in which the encapsulant is squeezed out from the outer peripheries of the glass member and the translucent member due to the heat-pressure bonding treatment can be suppressed. For this reason, a process of removing squeezed out encapsulant (a trimming process), which was essential as a process after the heat-pressure bonding treatment in the conventional production method of a solar cell module, becomes unnecessary.

Preferable embodiments of the glass member, the solar cell element, the encapsulant, the translucent member and the like will be described later.

FIG. 2 is a schematic cross-sectional view showing a module layered body 107A serving as one example of the module layered body 107.

As shown in FIG. 2, the configuration of the module layered body 107A is a configuration in which a back face protective member 25A serving as the glass member, an encapsulant 24A, a solar cell element 23A, an encapsulant 22A, and a translucent substrate 21A serving as the translucent member are layered in this order, and outer peripheries of the two encapsulants 22A and 24A are positioned at an inner side of peripheries of the back face protective member 25A and the translucent substrate 21A. The solar cell element 23A is present in a plurality thereof, and the solar cell elements 23A are respectively connected with conductive wires (also referred to as interconnectors).

The “translucent substrate” in the present invention is a member of the solar cell module (module layered body) and refers to a member that is arranged at a light-receiving face side (a side at which solar light is incident).

Further, the “back face protective member” in the present invention is a member of the solar cell module (module layered body) and refers to a member that is arranged at an opposite side from the light-receiving face side (a face at the opposite side is referred to as a “back face”) and is for protecting other members (the solar cell elements, the encapsulants, and the like).

FIG. 3 is a schematic cross-sectional view showing a module layered body 107B serving as another example of the module layered body 107.

As shown in FIG. 3, the configuration of the module layered body 107B is a configuration in which a back face protective member 25B serving as the glass member, an encapsulant 24B, a solar cell element 23B, and a translucent substrate 21B serving as the translucent member are layered in this order, and an outer periphery of the encapsulant 24B is positioned at an inner side of peripheries of the back face protective member 25B and the translucent substrate 21B. The solar cell element 23B is present in a plurality thereof, and the solar cell elements 23B are respectively connected with conductive wires (also referred to as interconnectors).

Embodiments of the module layered body 107B may be an embodiment in which the translucent substrate 21B and the solar cell element 23B are separate independent members, or may be an embodiment in which the translucent substrate 21B and the solar cell element 23B are integral members.

Examples of embodiments in which the translucent substrate 21B and the solar cell element 23B are integral members include an embodiment in which an amorphous silicon solar cell element serving as the solar cell element 23B is formed on a glass substrate serving as the translucent substrate 21B.

Next, a production method of a solar cell module using the laminator shown in FIG. 1 will be explained as an embodiment of the production method of a solar cell module of the present invention. However, the production method of a solar cell module of the present invention is not limited by the following embodiment.

### (First Process)

As operation of the first process, the lower chamber 104 is opened, and the module layered body 107 is mounted on the mounting platen 103 so that the translucent member is at the mounting platen 103 side and the glass member is at the diaphragm 101 side. Thereafter, the lower chamber 104 is closed.

### (Second Process)

After the first process, as operation of the second process, the inside of the upper chamber 102 and the inside of the lower chamber 104 are depressurized.

At this time, the inside of the upper chamber 102 and the inside of the lower chamber 104 may be depressurized simultaneously, or depressurization of the inside of the upper chamber 102 may be carried out before depressurization of the inside of the lower chamber 104 to suck the diaphragm 101 to the upper chamber 102 side.

The depressurization of the inside of the upper chamber 102 and the inside of the lower chamber 104 is respectively carried out by evacuating the inside of the chambers to a state that is close to that of a vacuum (for example, to less than 0.005 MPa, preferably to 0.004 MPa or less, and more preferably to from 0.0001 MPa to 0.004 MPa) using an unillustrated vacuum pump.

Utilizing the time it takes until the pressures inside the upper chamber 102 and inside the lower chamber 104 reach the targeted pressures, the module layered body 107 is heated by heating the mounting platen 103 by the heater 133.

Although the heating temperature at this time depends on the type of the encapsulant, from 100° C. to 200° C. is preferable, and from 120° C. to 180° C. is more preferable.

Due to the depressurization (evacuation) in the second process, gas components (air and the like) introduced between the respective members constituting the module layered body 107 and gas components (air and the like) introduced into the materials constituting the respective members are discharged.

At this time, in a case where the resin constituting the encapsulant is a resin that requires cross-linking (for example, EVA or the like including a cross-linking agent), the module layered body 107 is heated up to a temperature at which a cross-linking reaction occurs, and that temperature is maintained until the cross-linking reaction is concluded.

### (Third Process)

After the second process, as operation of the third process, the pressure inside the upper chamber 102 is raised to from 0.005 MPa to 0.090 MPa (a gauge pressure of from −0.096 MPa to −0.011 MPa). Specifically, for example, while continuing the evacuation of the inside of the lower chamber 104, the evacuation of the inside of the upper chamber 102 is stopped, and air, nitrogen or the like is supplied into the upper chamber 102 so that the pressure inside the upper chamber 102 becomes the aforementioned value.

By raising the pressure inside the upper chamber 102 so as to become the aforementioned value, a pressure difference between the inside of the upper chamber 102 and the inside of the lower chamber 104 is generated, and the diaphragm 101 undergoes flexural deformation toward the inside of the lower chamber 104, which is the low-pressure side.

The module layered body 107 is pressed to the mounting platen 103 by the diaphragm 101 which has undergone flexural deformation. The module layered body 107 is heat-pressure bonded by the pressure bonding force due to this pressing and by the temperature of the heated mounting platen 103. As a result, the resin constituting the encapsulant is softened or melted, and the module layered body 107 is integrated to obtain the solar cell module.

As the pressure inside the upper chamber 102 in the third process, from 0.005 MPa to 0.080 MPa is preferable from the standpoint of further suppressing deformation of the encapsulant.

As the time period for the heat-pressure bonding treatment, from 1 to 8 minutes is preferable, and from 2 to 6 minutes is more preferable.

The production method of a solar cell module in the present embodiment may comprise processes other than the aforementioned first to third processes in accordance with necessity.

After the third process, ordinarily, the pressure inside the lower chamber 104 is returned to atmospheric pressure, and the solar cell module is taken out from the lower chamber 104.

For example, after the third process, heating by the heater 133 is stopped, the upper chamber 102 and the lower chamber 104 are returned to atmospheric pressure, the lower chamber 104 which has been closed is next opened, and the solar cell module is taken out from the lower chamber 104. Thereafter, the solar cell module is cooled.

Next, preferable embodiments of the glass member, the solar cell element, the encapsulant, and the translucent member in the present invention will be explained.

### (Glass Member)

The glass member is not particularly limited, but a glass sheet or a glass plate that is ordinarily used in a solar cell module can be used.

Further, for example, a glass member having a surface compression stress of 20 MPa or more is preferable from the standpoints of durability with respect to heat cracking that accompanies temperature rise due to solar irradiation over a wide area and durability with respect to ballistic fragments. The surface compression stress of the glass member is a value that is measured in accordance with JIS R3222.

Examples of members made of glass having a surface compression stress of 20 MPa or more specifically include double strength glass, tempered glass, and ultra tempered glass.

The surface compression stress of the double strength glass is ordinarily from 20 MPa to 60 MPa, the surface compression stress of the tempered glass is ordinarily from 90 MPa to 130 MPa, and the surface compression stress of the ultra tempered glass is ordinarily from 180 MPa to 250 MPa.

The larger the surface compression stress becomes, the more the strength is increased, but warping tends to be increased, and production cost also tends to be increased. The double strength glass has advantages in that it allows easy production of glass with relatively little warping, and in that, when broken, it does not result in fine shards that fall away.

The glass serving as the material of the glass member is not particularly limited, but, for example, soda lime glass is preferably used. Further, heat reflecting glass, heat absorbing glass or the like can also be used.

Furthermore, as the glass, glass having a low content of iron (for example, non-iron (iron free) tempered glass) may also be used, and glass having a relatively high content of iron may also be used.

The non-iron (iron free) tempered glass is also referred to as, high transmittance glass and white sheet glass.

The glass having a relatively high content of iron is also referred to as blue sheet glass and float glass.

A thickness of the glass member is not particularly limited but is ordinarily 20 mm or less. From the standpoint of making the entire solar cell module thinner and lighter, the thickness of the glass member is preferably 4 mm or less, more preferably 3 mm or less, and even more preferably 2.5 mm or less.

In a case where the solar cell module of the present invention has a configuration comprising the glass member as the back face protective member, the encapsulant, the solar cell element, and the translucent substrate in this order, strength of the solar cell module is ordinarily maintained by the translucent substrate. Accordingly, in the solar cell module of this configuration, it is preferable to make the thickness of the glass member serving as the back face protective member thinner than a thickness of the translucent substrate from the standpoint of making the entire solar cell module thinner and lighter.

Although there is no restriction on the lower limit of the glass member, it is ordinarily 0.2 mm or more, and preferably 0.5 mm or more.

### (Solar Cell Element)

As the solar cell element, a conventionally known solar cell element, such as a crystalline silicon solar cell element, a polycrystalline silicon solar cell element, an amorphous silicon solar cell element, a copper indium selenide solar cell element, a compound semiconductor solar cell element, an organic dye solar cell element or the like, can be selected in accordance with the purpose thereof.

In addition to having excellent performance as a solar cell element, the amorphous silicon solar cell element has an advantage in that it can be easily formed on the translucent member in the form of a thin film. That is to say, in a case where the amorphous silicon solar cell element is used, a member in which the amorphous silicon solar cell element and the translucent member are integral can be used in the module layered body. For this reason, by using the amorphous silicon solar cell element, the entire solar cell module can be easily made thinner and lighter.

### (Translucent Member)

Although the translucent member is not particularly limited, when a translucent member having a bending elastic modulus of 1 GPa or more (or furthermore 10 GPa or more) is used as the translucent member, the effect of suppressing deformation of the encapsulant according to the invention is more effectively exerted.

As the translucent member, for example, a member made of engineering plastic (including super engineering plastic) or a glass member can be used.

Examples of a material of the member made of engineering plastic (including super engineering plastic) include a polyester resin, an acrylic resin, a fluorine-based resin, a polycarbonate (PC) resin, a polyether ether ketone (PEEK) resin, a polyphenylene sulfide (PPS) resin, a polyimide (PI) resin, a polyether sulfone (PES) resin, a polybutylene terephthalate (PBT) resin and the like.

The bending elastic modulus of the member made of engineering plastic is ordinarily from 1 GPa to 7 GPa.

Examples of preferable embodiments of the glass member in a case where it is used as the translucent member include similar embodiments to the embodiments described in the “glass member” section described above.

For example, the glass having a low content of iron (for example, the non-iron (iron free) tempered glass) may be used, and the glass having a relatively high content of iron may also be used.

The non-iron (iron free) tempered glass is also referred to as high transmittance glass and white sheet glass.

The glass having a relatively high content of iron is also referred to as blue sheet glass and float glass.

The bending elastic modulus of the glass also depends on the type of glass but is, for example, 73.5 GPa.

It is preferable that the translucent member is a glass member from the standpoint that the effect of suppressing deformation of the encapsulant is particularly remarkably obtained. That is to say, it is preferable that the configuration of the module layered body in the present invention is a configuration comprising a first glass member, the encapsulant, the solar cell element, and a second glass member as the translucent member in this order.

As the material of the glass member in a case where it is used as the translucent member, glass referred to as blue sheet glass or float glass is ordinarily used. In a case where it is desired to increase an amount of incident light that reaches the solar cell element, non-iron (iron free) tempered glass (that is to say, high transmittance glass or white sheet glass), which is excellent in transparency, is preferably selected.

### (Encapsulant)

The encapsulant is a member made of resin and is a member that encapsulates (seals) the solar cell element by itself or in cooperation with another member (for example, the translucent member) or the like.

Due to the encapsulant, the solar cell element is protected from temperature change, humidity, impact and the like. Further, the respective members of the module layered body (for example, the translucent member and the glass member) are adhered and integrated via the encapsulant.

Accordingly, there is a tendency for various capabilities, such as weather resistance, adhesiveness, additive holding capability, heat resistance, cold resistance, impact resistance, transparency in accordance with necessity, and the like, to be required of the encapsulant.

Examples of resins that satisfy these capabilities include an ethylene-vinyl acetate copolymer (EVA), an ethylene-methyl acrylate copolymer (EMA), an ethylene-ethyl acrylate copolymer (EEA), an ethylene-acrylic acid copolymer (EAA), an ethylene-methacrylic acid copolymer (EMMA), an ionomer of an ethylene-unsaturated carboxylic acid copolymer, polyethylene, modified polyethylene, a silicon resin, a urethane resin and the like. Further, in order to improve the heat resistance of these resins, a cross-linking agent or a cross-linking aid may be used in combination therewith in accordance with necessity.

From the standpoint that the effect of suppressing deformation of the encapsulant is more effectively exerted and the standpoint that corrosion of metal members constituting the module can be prevented due to a small moisture permeability rate, an ionomer of an ethylene-unsaturated carboxylic acid copolymer is particularly preferable as the encapsulant.

The ionomer of an ethylene-unsaturated carboxylic acid copolymer has a structure in which the ethylene-unsaturated carboxylic acid copolymer is a base polymer, and carboxylic acid groups contained in the base polymer have been cross-linked by metal ions.

The ethylene-unsaturated carboxylic acid copolymer serving as the base polymer is a copolymer in which ethylene and a monomer selected from unsaturated carboxylic acids have been copolymerized at least as copolymer components. In the ethylene-unsaturated carboxylic acid copolymer a monomer other than the unsaturated carboxylic acid may be copolymerized in accordance with necessity.

In the ethylene-unsaturated carboxylic acid copolymer, as content ratio of structural units derived from ethylene, from 97 to 75 mass percent is preferable, and from 95 to 75 mass percent is more preferable. In the ethylene-unsaturated carboxylic acid copolymer, as content ratio of structural units derived from unsaturated carboxylic acid, from 3 to 25 mass percent is preferable, and from 5 to 25 mass percent is more preferable.

It is preferable to make the ethylene-unsaturated carboxylic acid copolymer a binary random copolymer of ethylene and an unsaturated carboxylic acid copolymer.

When the content ratio of structural units derived from ethylene is 75 mass percent or more, heat resistance, mechanical strength and the like of the copolymer are good. On the other hand, when the content ratio of structural units derived from ethylene is 97 mass percent or less, adhesiveness and the like is good.

When the content ratio of structural units derived from unsaturated carboxylic acid is 3 mass percent or more, transparency and flexibility are good. Further, a copolymer in which the content ratio of structural units derived from unsaturated carboxylic acid is 25 mass percent or less, stickiness is suppressed, and processability is good.

Examples of the unsaturated carboxylic acid include, for example, unsaturated carboxylic acids or half esters having from 3 to 8 carbon atoms, such as acrylic acid, methacrylic acid, ethacrylic acid, itaconic acid, itaconic acid anhydride, fumaric acid, crotonic acid, maleic acid, maleic acid anhydride, maleic acid monoester (maleic acid monomethyl, maleic acid monoethyl and the like), maleic acid monoester anhydride (maleic acid monomethyl anhydride, maleic acid monoethyl anhydride and the like).

Among these, acrylic acid and methacrylic acid are preferable.

In the ethylene-unsaturated carboxylic acid copolymer, structural units derived from copolymerizable monomers other than ethylene and unsaturated carboxylic acid may be included in an amount of from more than 0 mass percent to 30 mass percent, and preferably of from more than 0 mass percent to 25 mass percent, with respect to 100 mass percent of a total amount of the ethylene and the unsaturated carboxylic acid.

Examples of the other copolymerizable monomers include unsaturated esters, for example, vinylesters such as vinyl acetate, vinyl propionate and the like; and (meth)acrylic acid esters such as methyl acrylate, ethyl acrylate, isobutyl acrylate, n-butyl acrylate, 2-ethylhexyl acrylate, methyl methacrylate, isobutyl methacrylate and the like. When structural units derived from copolymerizable monomers other than ethylene and unsaturated carboxylic acid are included in the aforementioned range, flexibility of the ethylene-unsaturated carboxylic acid copolymer is improved, and therefore, this is preferable.

Examples of the metal ions in the ionomer include monovalent metal ions such as lithium, sodium, potassium, cesium and the like, bivalent metal ions such as magnesium, calcium, strontium, barium, copper, zinc and the like, and trivalent metal ions such as aluminum, iron and the like. Among these, sodium, magnesium and zinc are preferable, and zinc is particularly preferable.

A degree of neutralization of the ionomer is preferably 80 percent or less, and more preferably from 5 percent to 80 percent. In view of processability and flexibility, the degree of neutralization is preferably from 5 percent to 60 percent, and more preferably from 5 percent to 30 percent.

The ethylene-unsaturated carboxylic acid copolymer serving as the base polymer of the ionomer can be obtained by subjecting the respective polymerization components to radical copolymerization under high temperature and high pressure. Furthermore, the ionomer can be obtained by causing such an ethylene-unsaturated carboxylic acid copolymer to react with zinc oxide, zinc acetate or the like.

In consideration of processability and mechanical strength, a melt flow rate of the ionomer at 190° C. and a load of 2160 g (MFR; in compliance with JIS K7210-1999) is preferably from 0.1 to 150 g/10 minutes, and particularly preferably from 0.1 to 50 g/10 minutes.

A melting point of the ionomer is not particularly limited, but when the ionomer has a melting point of 90° C. or higher, and particularly 95° C. or higher, it is preferable in that heat resistance becomes good.

A content of the ionomer with respect to the total solid component of the encapsulant is preferably 60 mass percent or more, more preferably 70 mass percent or more, and particularly preferably 80 mass percent or more. When the content of the ionomer is in the aforementioned ranges, good adhesiveness, durability and the like are obtained while maintaining high transparency.

In a case where the content of the ionomer with respect to the total solid component of the encapsulant is not 100 mass percent, other resin material may be mixed together with the ionomer. As the resin material that is mixed in such a case, any material can be used as long as it has good compatibility with the ionomer and does not impair transparency and mechanical properties. Among these, an ethylene-unsaturated carboxylic acid copolymer and an ethylene-unsaturated ester-unsaturated carboxylic acid copolymer are preferable. If the resin material that is mixed with the ionomer is a resin material that has a melting point that is higher than that of the ionomer, it is also possible to improve the heat resistance and durability of the encapsulant.

Components other than resin may be included in the encapsulant.

Examples of the other components include a silane coupling agent, an ultraviolet absorbing agent, a light stabilizer, an oxidation inhibitor, a colorant, a light diffusing agent, a flame retardant, a metal deactivator and the like.

A thickness of the encapsulant is not particularly limited but is preferably from 100 μm to 1000 μm, and more preferably from 200 μm to 800 μm.

The preferable range of the size of the encapsulant is as described above.

### EXAMPLES

The present invention will be explained more concretely below by way of examples, but the present invention is not limited by the following examples.

### Example 1

### Preparation of Solar Cell Module

Using a laminator (a LM-50×50-S vacuum laminator manufactured by NPC Incorporated) having the same configuration as the double vacuum chamber system laminator shown in FIG. 1, a module layered body having the same configuration as the module layered body 107B shown in FIG. 3 was integrated to prepare a solar cell module. The detailed method is described below.

### (First Process)

A white sheet glass (non-iron (iron free) tempered glass having a bending elastic modulus of 73.5 GPa) with a size of 300 mm×300 mm×4 mm thickness, an encapsulant sheet made of an ionomer of an ethylene-unsaturated carboxylic acid copolymer (Himilan ES (brand: PV8615A) manufactured by Du Pont-Mitsui Polychemicals Co., Ltd.) with a size of 250 mm×250 mm×0.3 mm thickness, and a white sheet glass (non-iron (iron free) tempered glass having a bending elastic modulus of 73.5 GPa) with a size of 300 mm×300 mm×4 mm thickness having formed thereon an amorphous silicon solar cell element were layered in this order, with an orientation by which the amorphous silicon solar cell element and the encapsulant sheet contact each other, to obtain a module layered body (a). At this time, by layering the three aforementioned members so that centers thereof overlap, an outer periphery of the encapsulant sheet was positioned at an inner side of outer peripheries of the two white sheet glasses.

Next, the lower chamber was opened, and the aforementioned module layered body (a) was mounted on the mounting platen in the lower chamber with an orientation by which the white sheet glass on which the amorphous silicon solar cell element was not formed and the diaphragm contact each other (that is to say, an orientation by which the white sheet glass having the amorphous silicon solar cell element formed thereon and the surface of the mounting platen contact each other).

Thereafter, the lower chamber was closed. In a state in which the lower chamber was closed, a distance (clearance) between the module layered body and the diaphragm was 50 mm.

### (Second Process)

After the first process, the inside of the upper chamber and the inside of the lower chamber were evacuated for three minutes with a vacuum pump, and pressures of the upper chamber and the lower chamber were both adjusted to 0.001 MPa (gauge pressure of −0.100 MPa). During the three minutes of evacuation, the mounting platen was heated to 150° C.

### (Third Process)

After the second process, evacuation of the upper chamber was stopped, and air was introduced into the upper chamber such that the pressure inside the upper chamber became 0.071 MPa (gauge pressure of −0.030 MPa). As a result, the diaphragm made of silicon rubber was subjected to flexural deformation to the lower chamber side, and the module layered body (a) was pressed to the mounting platen by the diaphragm which had undergone flexural deformation.

This state was maintained for five minutes, and the module layered body was heat-pressure bonded (laminated) and integrated to obtain a solar cell module.

After the third process, heating of the mounting platen was stopped, air was introduced into the lower chamber so that the pressure inside the lower chamber became atmospheric pressure (0.101 MPa; gauge pressure of 0 MPa), and simultaneously, evacuation of the inside of the upper chamber was carried out so that the pressure in the upper chamber became 0.001 MPa (gauge pressure of −0.100 MPa).

Thereafter, the lower chamber was opened, and the solar cell module was taken out.

### <Evaluation>

The following evaluation was carried out with respect to the aforementioned solar cell module.

The evaluation results are shown in the following Table 1.

### (Evaluation of Air Bubbles)

With respect to the solar cell module taken out as mentioned above, the presence or absence of air bubbles of 0.5 mm or larger was confirmed by visual observation, and evaluation was carried out according to the following evaluation criteria.

### —Evaluation Criteria for Air Bubbles—

A: Air bubbles of 0.5 mm or larger were not confirmed.
B: Air bubbles of 0.5 mm or larger were confirmed.

### (Evaluation of the Shape of the Corner Portions of the Encapsulant Sheet)

With respect to the solar cell module taken out as mentioned above, the corner portions at the four corners of the encapsulant sheet were observed by visual observation and evaluated according to the following evaluation criteria.

An evaluation result of “A” indicates that deformation of the encapsulant is suppressed.

### —Evaluation Criteria for the Shape of the Corner Portions of the Encapsulant Sheet—

A: The corner portions at the four corners of the encapsulant sheet maintained 90° angles, or deformation was restrained to a rounded shape having a radius of curvature of 2 mm or less (for example, refer to FIG. 5).
B: The corner portions at the four corners of the encapsulant sheet were deformed in a rounded shape having a radius of curvature exceeding 2 mm (for example, refer to FIG. 6).

### (Evaluation of Uniform Expandability of the Encapsulant Sheet)

The module layered body (a) prepared in the first process and the solar cell module obtained by the module layered body (a) being heat-pressure bonded and integrated were compared, and uniform expandability of the encapsulant sheet due to the heat-pressure bonding treatment (that is, uniformity of spreading of the encapsulant sheet) was measured in the following manner.

First, attention was focused on one side of the encapsulant sheet, and spreading of the encapsulant sheet due to the heat-pressure bonding treatment (distance of movement of the one side due to the heat-pressure bonding treatment) was measured. At this time, since there are cases where the magnitude of spreading differs according to location within one side, a maximum value and a minimum value of the spreading were found for the one side.

In the same manner, a maximum value and a minimum value of spreading were also found for each of the other three sides of the encapsulant sheet.

An average of the four maximum values obtained above was designated as an average maximum value of spreading of the encapsulant sheet (designated hereinafter as an “α value”), and an average of the four minimum values obtained above was designated as an average minimum value of spreading of the encapsulant sheet (designated hereinafter as a “β value”). An absolute value of the difference between the aforementioned a value and the aforementioned 13 value was found, and uniform expandability of the encapsulant sheet was evaluated according to the following evaluation criteria.

An evaluation result of “A” indicates that deformation of the encapsulant is suppressed.

### —Evaluation Criteria for Uniform Expandability of the Encapsulant Sheet—

A: The absolute value of the difference between the aforementioned α value and the aforementioned β value was less than 2 mm (for example, refer to FIG. 5).
B: The absolute value of the difference between the aforementioned α value and the aforementioned β value was 2 mm or greater (for example, refer to FIG. 6).

### Example 2

Except for changing the module layered body (a) in Example 1 to a module layered body (b) obtained by layering a blue sheet glass (float glass having a bending elastic modulus of 73.5 GPa) with a size of 250 mm×250 mm×3.9 mm thickness, an encapsulant sheet made of an ionomer of an ethylene-unsaturated carboxylic acid copolymer (Himilan ES (brand: PV8615A) manufactured by Du Pont-Mitsui Polychemicals Co., Ltd.) with a size of 210 mm×210 mm×0.3 mm thickness, and a blue sheet glass (float glass having a bending elastic modulus of 73.5 GPa) with a size of 250 mm×250 mm×3.9 mm thickness having formed thereon an amorphous silicon solar cell element in this order, with an orientation by which the amorphous silicon solar cell element and the encapsulant sheet contact each other, a solar cell module was prepared in the same manner as in Example 1, and evaluation was carried out in the same manner as in Example 1.

The evaluation results are shown in Table 1.

### Examples 3 and 4

Except for changing the size of the encapsulant made of the ionomer in Example 2 to 245 mm×245 mm×0.3 mm thickness (the module layered body obtained according to this change is designated hereinafter as a “module layered body (c)”), and changing the pressure of the upper chamber in the third process as shown in the following Table 1, solar cell modules were prepared in the same manner as in Example 2, and evaluation was carried out in the same manner as in Example 2.

The evaluation results are shown in Table 1.

### Example 5

Except for changing the encapsulant sheet in Example 3 to an encapsulant sheet layered body obtained by layering two of these encapsulant sheets and having a total thickness of 0.6 mm (the module layered body obtained according to this change is designated hereinafter as a “module layered body (d)”), a solar cell module was prepared in the same manner as in Example 3, and evaluation was carried out in the same manner as in Example 3.

The evaluation results are shown in Table 1.

### Example 6

Except for changing the thickness of each of the two blue sheet glasses in Example 3 to 1.1 mm, and the size of the encapsulant made of the ionomer to 247 mm×247 mm×0.3 mm thickness (the module layered body obtained according to these changes is designated hereinafter as a “module layered body (e)”), a solar cell module was prepared in the same manner as in Example 3, and evaluation was carried out in the same manner as in Example 3.

The evaluation results are shown in Table 1.

### Comparative Example 1

Except for changing the pressure of the upper chamber in the third process in Example 1 to atmospheric pressure (0.101 MPa) as shown in the following Table 1, a solar cell module was prepared in the same manner as in Example 1, and evaluation was carried out in the same manner as in Example 1.

The evaluation results are shown in Table 1.

### Comparative Example 2

Except for changing the module layered body (a) in Example 1 to a module layered body (f) obtained by layering a white sheet glass (non-iron (iron free) tempered glass having a bending elastic modulus of 73.5 GPa) with a size of 300 mm×300 mm×4 mm thickness, a sheet of an ethylene-vinyl acetate copolymer containing a cross-linking agent with a size of 250 mm×250 mm×0.3 mm thickness, a crystalline silicon solar cell element, a sheet of an ethylene-vinyl acetate copolymer containing a cross-linking agent with a size of 250 mm×250 mm×0.3 mm thickness, and a white sheet glass (non-iron (iron free) tempered glass having a bending elastic modulus of 73.5 GPa) with a size of 300 mm×300 mm×4 mm thickness in this order, and changing the pressure of the upper chamber in the third process as shown in the following Table 1, a solar cell module was prepared in the same manner as in Example 1, and evaluation was carried out in the same manner as in Example 1.

The evaluation results are shown in Table 1.

### Comparative Examples 3 and 4

Except for changing the pressure of the upper chamber in the third process in Example 2 as shown in the following Table 1, solar cell modules were prepared in the same manner as in Example 2, and evaluation was carried out in the same manner as in Example 2.

The evaluation results are shown in Table 1.

TABLE 1

| | Lamination Pressure | | | Evaluation Results | | |
|---|---|---|---|---|---|---|
| | Absolute | Gauge | Module | Air | Shape of | Uniform |
| | Pressure | Pressure | Layered | Bub- | Corner | Expand- |
| | (MPa) | (MPa) | Body | bles | Portions | ability |
| Example 1 | 0.071 | −0.030 | a | A | A | A |
| Example 2 | 0.071 | −0.030 | b | A | A | A |
| Example 3 | 0.061 | −0.040 | c | A | A | A |
| Example 4 | 0.007 | −0.094 | c | A | A | A |
| Example 5 | 0.061 | −0.040 | d | A | A | A |
| Example 6 | 0.061 | −0.040 | e | A | A | A |
| Com. | 0.101 | 0 | a | B | B | B |
| Ex. 1 | | | | | | |
| Com. | 0.094 | −0.007 | f | A | B | B |
| Ex. 2 | | | | | | |
| Com. | 0.101 | 0 | b | B | B | B |
| Ex. 3 | | | | | | |
| Com. | 0.003 | −0.098 | b | — | — | — |
| Ex. 4 | | | | | | |

In Table 1, the “Lamination Pressure” refers to the pressure of the upper chamber in the third process (the same applies hereinafter).

As show in Table 1, in Examples 1-6 in which the lamination pressure is within the range of from 0.005 MPa to 0.090 MPa, generation of air bubbles was suppressed. Furthermore, in Examples 1-6, the shape of the corner portions of the encapsulant sheet and uniform expandability was excellent, and deformation of the encapsulant sheet due to the heat-pressure bonding treatment was suppressed. Particularly in Examples 3-6, end faces of the two sheets of glass and an end face of the encapsulant sheet were neatly lined up (that is to say, outer peripheries of the two sheets of glass and an outer periphery of the encapsulant sheet overlapped) at the outer periphery of the module layered body after the heat-pressure bonding treatment.

Further, in Comparative Example 4 in which the lamination pressure was too low, it was not possible to integrate the module layered body. In contrast, in Example 4 in which the lamination pressure was slightly higher than in Comparative Example 4, it was possible to integrate the module layered body while suppressing generation of air bubbles and suppressing deformation of the encapsulant sheet.

FIG. 4 is a photograph showing a corner portion of the glass substrate in the solar cell module according to Comparative Example 1.

As shown in FIG. 4, air bubbles were generated in the corner portion of the glass substrate.

FIG. 5 is a photograph showing the entirety of the solar cell module according to Example 2.

As shown in FIG. 5, in the solar cell module according to Example 2, even after the heat-pressure bonding treatment, the shape of the corner portions of the encapsulant sheet were maintained at 90° angles, and the encapsulant sheet was spread uniformly by the heat-pressure bonding treatment. Thus, in the solar cell module according to Example 2, deformation of the encapsulant due to the heat-pressure bonding treatment was suppressed.

FIG. 6 is a photograph showing the entirety of the solar cell module according to Comparative Example 3.

As shown in FIG. 6, in the solar cell module according to Comparative Example 3, the shape of the corner portions of the encapsulant sheet was changed to a rounded shape by the heat-pressure bonding treatment. Further, in the solar cell module according to Comparative Example 3, the encapsulant sheet was spread non-uniformly by the heat-pressure bonding treatment. That is to say, when attention is focused on one side of the encapsulant sheet, the amount of spreading was small at a center portion of the one side, while the amount of spreading was large at end portions of the one side, and as a result, the center portion of the one side has a shape that deforms inward toward the inner side. Thus, in the solar cell module according to Comparative Example 3, deformation of the encapsulant due to the heat-pressure bonding treatment was notable.

The entire disclosure of Japanese Patent Application No. 2010-157205 is incorporated herein into this specification by reference.

All documents, patent applications and technical standards mentioned in this specification are incorporated herein by reference to the same extent as if each individual document, patent application and technical standard was specifically and individually indicated to be incorporated by reference.

1. A production method of a solar cell module, comprising:
a first process of mounting a module layered body, which comprises at least a glass member, an encapsulant, a solar cell element and a translucent member in this order, and in which an outer periphery of the encapsulant is positioned at an inner side of outer peripheries of the glass member and the translucent member, on a mounting platen of a double vacuum chamber system laminator comprising a flexible member, a first chamber and a second chamber that are partitioned by the flexible member, and the mounting platen, which is provided in the second chamber facing the flexible member and comprises a heating means, the module layered body being mounted on the mounting platen so that the glass member is at the flexible member side;
a second process of depressurizing the inside of the first chamber and the inside of the second chamber after the first process; and
a third process of heat-pressure bonding and integrating the module layered body by raising a pressure in the first chamber to from 0.005 MPa to 0.090 MPa (gauge pressure of from −0.096 MPa to −0.011 MPa) and pressing the module layered body to the heated mounting platen by the flexible member which has undergone flexural deformation, after the second process.

2. The production method of a solar cell module according to claim 1, wherein a bending elastic modulus of the translucent member is 1 GPa or greater.

3. The production method of a solar cell module according to claim 1, wherein the translucent member is a glass member.

4. The production method of a solar cell module according to claim 1, wherein the encapsulant comprises an ionomer of an ethylene-unsaturated carboxylic acid copolymer.

5. The production method of a solar cell module according claim 1, wherein the module layered body comprises the encapsulant and the glass member, in this order, on an amorphous silicon solar cell element of the translucent member, on which the amorphous silicon solar cell element is formed.

6. The production method of a solar cell module according to claim 1, wherein the module layered body comprises the encapsulant, which contains an ionomer of an ethylene-unsaturated carboxylic acid copolymer, and the glass member, in this order, on an amorphous silicon solar cell element of the translucent member, on which the amorphous silicon solar cell element is formed.

7. The production method of a solar cell module according to claim 1, wherein a thickness of the glass member is 4 mm or less.

8. The production method of a solar cell module according to claim 1, wherein a distance between the outer periphery of the encapsulant and the outer peripheries of the glass member and the translucent member is from 1.5 mm to 25 mm.
